(19) United States
(12) Patent Application Publication
(10) Pub. No.: US 2026/0065147 A1
(43) Pub. Date: Mar. 5, 2026

(54) DESIGN ASSISTANCE SYSTEM, DESIGN ASSISTANCE PROGRAM, AND DESIGN ASSISTANCE METHOD

(71) Applicant: Hitachi, Ltd., Tokyo (JP)

(72) Inventor: Tatsuya HASEBE, Tokyo (JP)

(21) Appl. No.: 19/107,097

(22) PCT Filed: Sep. 25, 2023
(86) PCT No.: PCT/JP2023/034623

§ 371 Date: Feb. 27, 2025

(30) Foreign Application Priority Data
Nov. 2, 2022 (JP) 2022-176113

(51) Int. Cl. G06N 20/00

(52) U.S. Cl. CPC G06N 20/00

(57) ABSTRACT

The number of processes at the time of performing design of assigning 3DA feature quantities to a CAD model such as a three-dimensional CAD model is decreased. Assignment errors and writing omissions of 3DA feature quantities for a CAD model are reduced. A design assistance device 10 predicting 3DA feature quantities which are defined on a CAD model and which are related information of a target object of design has: a learning unit 102 constructing a learning model 115 used for predicting the 3DA feature quantities using an assigned CAD model 113 that is a CAD model to which the 3DA feature quantities and physical feature quantities representing physical features have been assigned; a connecting unit 107 receiving a CAD model 114 of the target object; and a 3DA predicting unit 108 predicting 3DA feature quantities to be assigned to the received CAD model 114 using the learning model 115.

### TECHNICAL FIELD

The present invention relates to a design assistance system, a design assistance program, and a design assistance method for assisting design of products and the like.

### BACKGROUND ART

Currently, target objects such as products are designed using computer aided design (CAD) systems. For example, in three-dimensional computer-aided design (hereafter referred to as three-dimensional CAD), a designer creates a three-dimensional shape of a product on a computer using techniques including solid modeling and parametric modeling. In most three-dimensional CAD software, the three-dimensional shape is represented using a Boundary REPresentation (BREP) that describes solids, faces, sides, and points of the shape and topology information thereof. Hereinafter, a three-dimensional shape created using the three-dimensional CAD software described above will be referred to as a 3D CAD model.

Here, in the 3D CAD model, 3DA feature quantities are used. In these 3DA feature quantities, an annotation and an attribute are included. The annotation is annotation information that includes information such as a tolerance, a weld, surface finish, and the like applied to a shape that includes solids, faces, sides, points, and the like in a CAD model. The attribute is attribute information to which various forms of information including a component type and specifications are assigned. This 3DA feature quantity is mainly used for describing product requirements, manufacturing requirements, and manufacturing instructions. In accordance with such a 3DA feature quantity, information required for various processes such as a design process, a production technology review process, a manufacturing process, and the like can be stored centrally in a 3D CAD model, which is regarded as facilitating the automation of manufacturing procedures.

Meanwhile, setting 3DA feature quantities in a 3D CAD model requires an operation on three-dimensional CAD software and thus requires a certain level of effort. For this reason, as a technology for assisting product design including annotations to a 3D CAD model, Patent Literature 1 has been proposed. In Patent Literature 1, identified details are associated with component gap information of a product designed in the past. Furthermore, a device that, when designing a new product, uses information on gaps between parts to present the designer with information on details that have been identified in similar past products, as well as text contained in the details that have been identified, annotations on the details that have been identified, and images of dimensional information, has been disclosed.

### CITATION LIST

### Patent Literature

Patent Literature 1: Japanese Patent Application Publication No. 2018-180578

### SUMMARY OF INVENTION

### Technical Problem

However, in Patent Literature 1, there are the following problems. In Patent Literature 1, a design that takes into consideration past identified details found through searching using the component gap information can be performed. However, it is very difficult to decrease the number of processes for assigning 3DA feature quantities such as annotations that are annotation information and the like. In order to assign 3DA feature quantities, although shape information of faces, sides, and the like that are targets for assignment needs to be taken into account, in Patent Literature 1, physical feature quantities such as shape feature quantities including features of faces and sides of each component are not taken into account. Thus, 3DA feature quantities such as annotation information and the like cannot be assigned to a CAD model such as a 3D CAD model and the like.

### Solution to Problem

In order to solve the problems described above, according to the present invention, a learning model is constructed by learning a relation between physical feature quantities representing physical features of a target object in a CAD model and 3DA feature quantities, and 3DA feature quantities of the target object in an input CAD model are predicted using the constructed learning model.

More specifically, there is provided a design assistance system predicting 3DA feature quantities which are defined on a CAD model and which are related information of a target object of design, the design assistance system including: a learning unit constructing a learning model used for predicting the 3DA feature quantities using an assigned CAD model that is a CAD model to which the 3DA feature quantities and physical feature quantities representing physical features have been assigned; a connecting unit receiving a CAD model of the target object; and a 3DA predicting unit predicting 3DA feature quantities to be assigned to the received CAD model using the learning model. In addition, the design assistance system may be realized by one device that is a design assistance device. In addition, in the present invention, a program for causing a design assistance device to function as a computer and a storage medium storing this program thereon belong to the present invention as well.

### Advantageous Effects of Invention

According to the present invention, 3DA feature quantities can be assigned to a CAD model by employing a simple configuration.

### BRIEF DESCRIPTION OF DRAWINGS

FIG. 1 is a functional block diagram of a design assistance device according to one embodiment of the present invention.

FIG. 2 is a diagram for describing 3DA feature quantities according to one embodiment of the present invention.

FIG. 3 is a diagram illustrating one example of a display screen of a display unit according to one embodiment of the present invention.

FIG. 4 is a diagram illustrating another example of a display screen of a display unit according to one embodiment of the present invention.

FIG. 5 is a flowchart illustrating a processing flow for learning a relationship between 3DA feature quantities and a CAD model according to one embodiment of the present invention.

FIG. 6 is a diagram illustrating one example of 3DA feature quantities, an adjacency graph, and physical feature quantities according to one embodiment of the present invention.

FIG. 7 is a flowchart illustrating a processing flow using a learning model according to one embodiment of the present invention.

FIG. 8 is a diagram illustrating Implementation Example 1 in which a design assistance device according to one embodiment of the present invention is implemented on a computer.

FIG. 9 is a diagram illustrating Implementation Example 2 in which a design assistance device according to one embodiment of the present invention is implemented on a computer (server).

### DESCRIPTION OF EMBODIMENTS

Hereinafter, one embodiment of the present invention will be described with reference to the drawings. In this embodiment, assistance is provided for the design of target objects such as a product, components configuring this product, and the like. In this design, generation and use of a CAD model including a 3D CAD model representing target objects are included. In design of a target object, it is preferable to use a CAD program such as a 3D CAD program and CAD software such as a design assistance program. In this embodiment, by using a design assistance device 10, information relating to a target object, more preferably, 3DA feature quantities that are feature quantities used in a manufacturing process or a maintenance process for the target object are predicted and assigned.

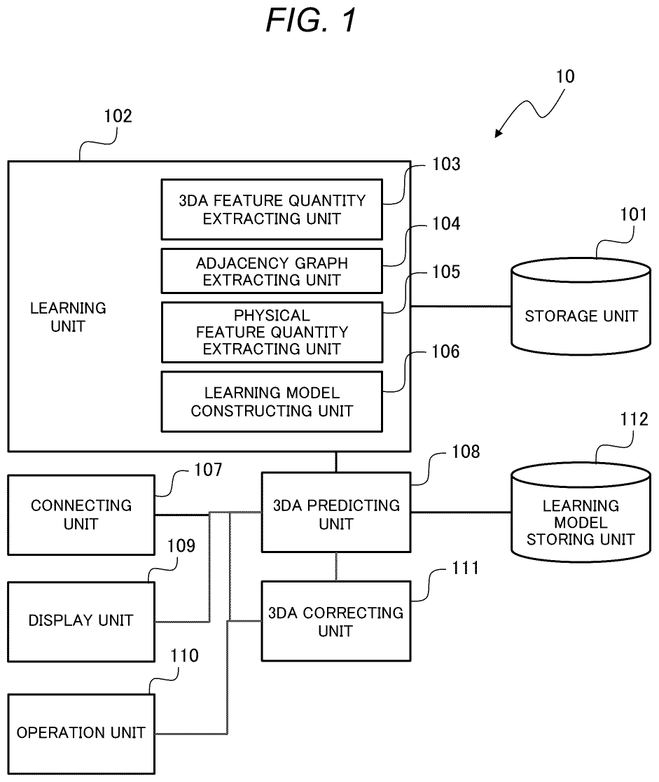

FIG. 1 is a functional block diagram of a design assistance device 10 according to this embodiment. The design assistance device 10 includes a storage unit 101, a learning unit 102, a learning model constructing unit 106, a connecting unit 107, a 3DA predicting unit 108, a display unit 109, an operation unit 110, a 3DA correcting unit 111, and a learning model storing unit 112.

First, in the storage unit 101, a plurality of assigned CAD models 113 to which 3DA feature quantities are assigned are stored. The 3DA feature quantities according to this embodiment include annotation information (annotations), attribute information (attributes), and auxiliary information relating to a target object. These (1) may be designated in specifications of Step 242 or the like, (2) may be independently designated by a three-dimensional CAD software vendor, or (3) may be included in an external file that is stored in a format associated with each part of the assigned CAD model 113. Here, a part is a unit configuring a target object, and, as the part, a face, a side, a unit solid, or a solid can be used. In addition, the assigned CAD model 113 can use history information generated in the past. In the assigned CAD model 113, information including a BREP representation of shape data of an assembly or a component is included. The design assistance device 10 according to this embodiment stores the assigned CAD model 113 in the storage unit 101. However, this is a preferred example, and it is not essential that the assigned CAD model 113 be stored in the storage unit 101, and a configuration in which an assigned CAD model 113 and the like are acquired from the connecting unit 107 or the operation unit 110 may be employed. In addition, the storage unit 101 may be omitted from the design assistance device 10.

The learning unit 102 includes a 3DA feature quantity extracting unit 103, an adjacency graph extracting unit 104, a physical feature quantity extracting unit 105, and a learning model constructing unit 106. The learning unit 102 reads the assigned CAD model 113 from the storage unit 101 and performs the following processes in respective parts thereof. The 3DA feature quantity extracting unit 103 extracts 3DA feature quantities from the assigned CAD model 113. For example, annotation information and attribute information are extracted. In addition, the adjacency graph extracting unit 104 generates an adjacency graph on the basis of topology information (phase information) of faces and sides of a target object included in the assigned CAD model 113 and information of a spatial adjacency relation of the faces.

The physical feature quantity extracting unit 105 extracts geometric shape features such as types of shapes of faces and sides of the target object, a normal-line direction, a curvature, an area, a convexity, and the like and associates them with nodes and edges of the adjacency graph. In addition, the physical feature quantity extracting unit 105 also associates 3DA feature quantities extracted by the 3DA feature quantity extracting unit 103 with the adjacency graph. Here, the topology information and shape information are examples of physical feature quantities representing physical features of a target object.

By using an adjacency graph associated with the 3DA feature quantity or the physical feature quantity described above, the learning unit 102 performs learning of a relationship between the adjacency graph and the 3DA feature quantity. Then, the learning unit 102 stores a learning model 115 associating a 3DA feature quantity, an adjacency graph, a method of extracting a physical feature quantity and logics of learning thereof, and data such as weights of machine learning generated as a result of learning with each other in the learning model storing unit 112. This learning model 115 includes likelihoods of types of 3DA feature quantities to be assigned, numerical values of properties of the 3DA feature quantities, and the like for solids, faces, and sides.

The connecting unit 107 inputs a CAD model 114 that is a prediction target of 3DA feature quantities. In this way, 3DA feature quantities are not assigned or insufficient for the CAD model 114. The input to the connecting unit 107 may be realized through a user interface such as an input device or a display or may be realized using a method including communication between servers or the like through an application protocol interface (API).

The 3DA predicting unit 108 predicts 3DA feature quantities of a target object included in the input CAD model 114. More specifically, the 3DA predicting unit 108 reads a learning model 115 of the learning model storing unit 112. Then, the 3DA predicting unit 108 predicts 3DA feature quantities for parts such as each solid, each face, each side, and the like of the CAD model 114 input by the connecting unit 107 using a method of extracting a physical feature quantity and an adjacency graph, learning logics, and learning results included in the learning model 115. In addition, the 3DA predicting unit 108 executes events such as an operation on the user interface, an input, a change, and the like for the CAD model 114, and the like as triggers.

The display unit 109 displays at least some of 3DA feature quantities predicted by the 3DA predicting unit 108, thereby presenting them to a user. For example, some of the predicted 3DA feature quantities of which the prediction reliability is high are presented to a user. The presentation to the user can be performed through a display device including a display.

The operation unit 110 can be realized by an input device such as a mouse, keyboard, a touch panel, or the like for a user. In addition, the operation unit 110 receives prediction results of 3DA feature quantities displayed in the display unit 109 and an operation on a user interface or an API of the CAD model from a user using a method including an operation of the API. In accordance with this, conversion of presented details, an operation of reflecting a predicted 3DA into

The 3DA correcting unit 111 corrects or adds 3DA feature quantities predicted by the 3DA predicting unit 108 for the CAD model 114 and records resultant 3DA feature quantities.

Then, the 3DA correcting unit 111 stores this result in the storage unit 101. At this time, it is preferable that the 3DA correcting unit 111 also use physical feature quantities including shape information. The correction of 3DA feature quantities may be performed in accordance with an operation on the operation unit 110 or may be automatically performed on the basis of the prediction result acquired by the 3DA predicting unit 108.

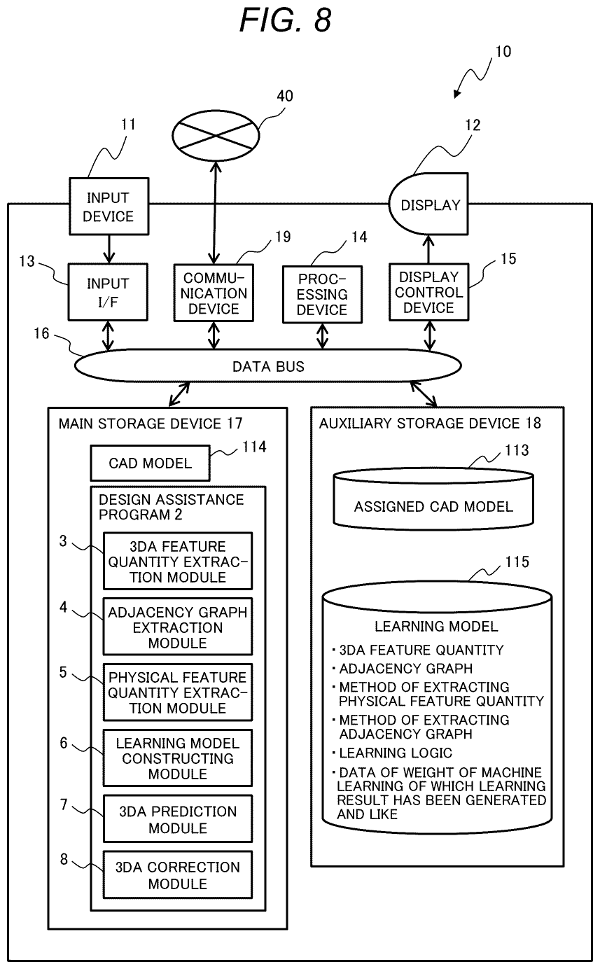

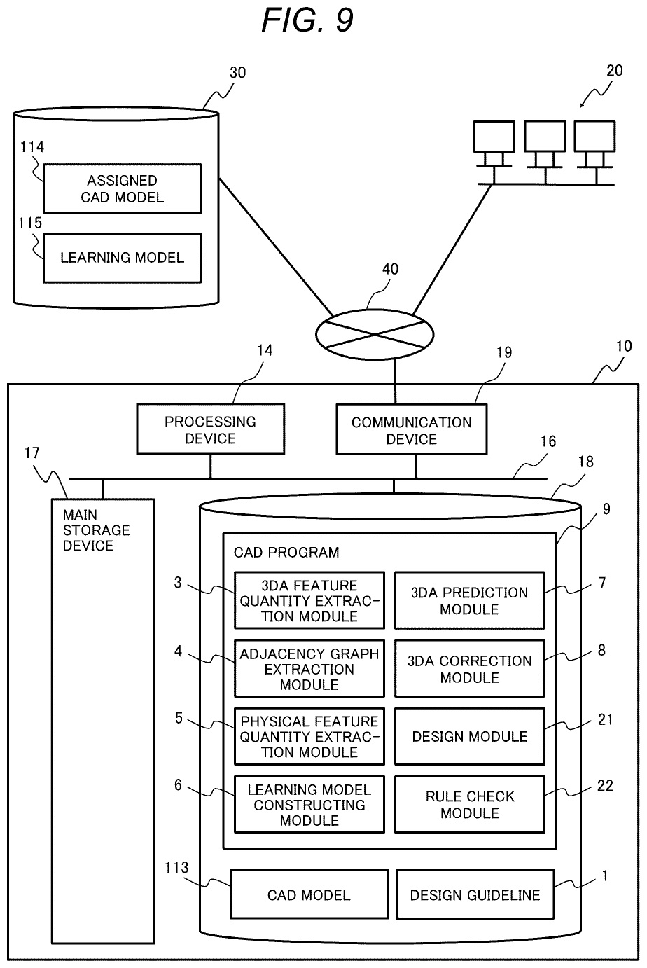

A physical form of the design assistance device 10 according to this embodiment can be realized by arranging components including the storage unit 101 to the 3DA correcting unit 111 on a single computer. Alternatively, the storage unit 101 to the 3DA predicting unit 108 may be arranged on a server that can be operated through a network or the like using an API, and the display unit 109 to the 3DA correcting unit 111 may be arranged on a computer that can be operated by a user as client programs. Alternatively, components including the storage unit 101 to the 3DA correcting unit 111 may be arranged on a server that can be operated through a network, and an input, a display, and an operation may be configured to be performed through an API. As the API, an API using a static or dynamic link of a binary program based on public program specifications and an API using network communication based on a communication protocol such as HyperText Transfer Protocol (HTTP) or the like are included. Specific examples of the description presented above will be described with reference to FIGS. 8 and 9 as Implementation Examples 1 and 2. In addition, the design assistance device 10 may be configured as a design assistance system having a learning device including the learning unit 102, the 3DA predicting unit 108, and the 3DA correcting unit 111.

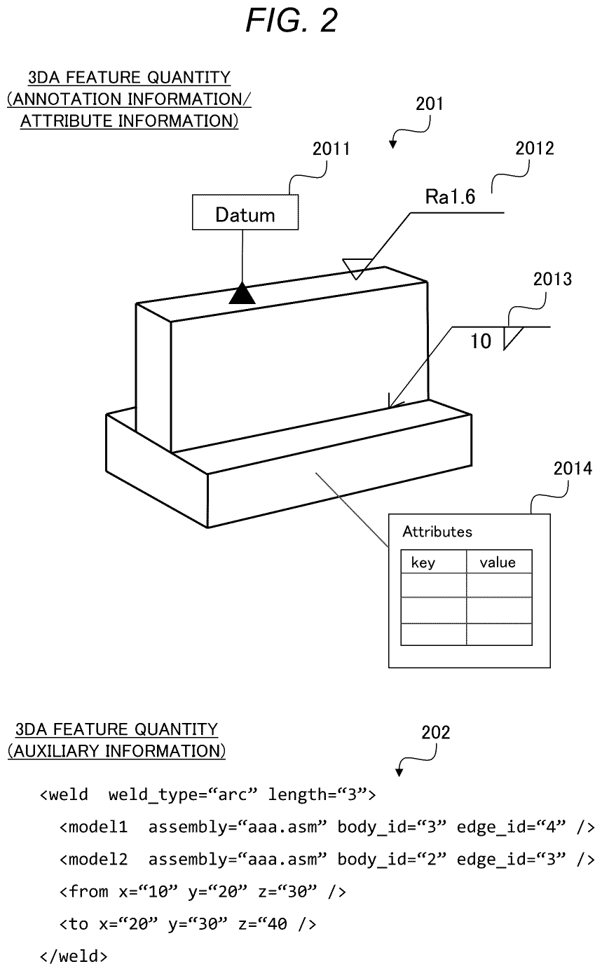

Next, 3DA feature quantities according to this embodiment will be described. FIG. 2 is a diagram for describing 3DA feature quantities according to this embodiment. The 3DA feature quantities illustrated in FIG. 2 include annotation information and attribute information (annotation information/attribute information 201) and auxiliary information 202 of a target object. The annotation information/attribute information 201 may be defined using the specifications of Step 242 or specifications that are independently defined by a 3D CAD software vendor or the like. The auxiliary information 202 is externally defined with respect to the CAD model and is described in association with sides and faces in the CAD model. FIG. 2 illustrates an example in which datum 2011, surface finish 2012, welding 2013, and attribute information 2014 of a key-value format on the periphery of a CAD model object illustrating a CAD model in the drawing are assigned to faces and sides in the CAD model as the annotation information/attribute information 201.

Among these, the datum 2011, the surface finish 2012, and the welding 2013 are annotation information, and these are displayed as symbols in the drawing.

In addition, an example in which welding information (a welding start point, an end point, and a corresponding shape) is designated in an XML format as the auxiliary information 202 is illustrated. In the auxiliary information 202, CAD models referring to corresponding faces and sides and IDs of faces and edges are described, whereby the sides and faces are associated with the CAD models. As described above, in the 3DA feature quantities, a feature for each part of the target object is associated with a CAD model.

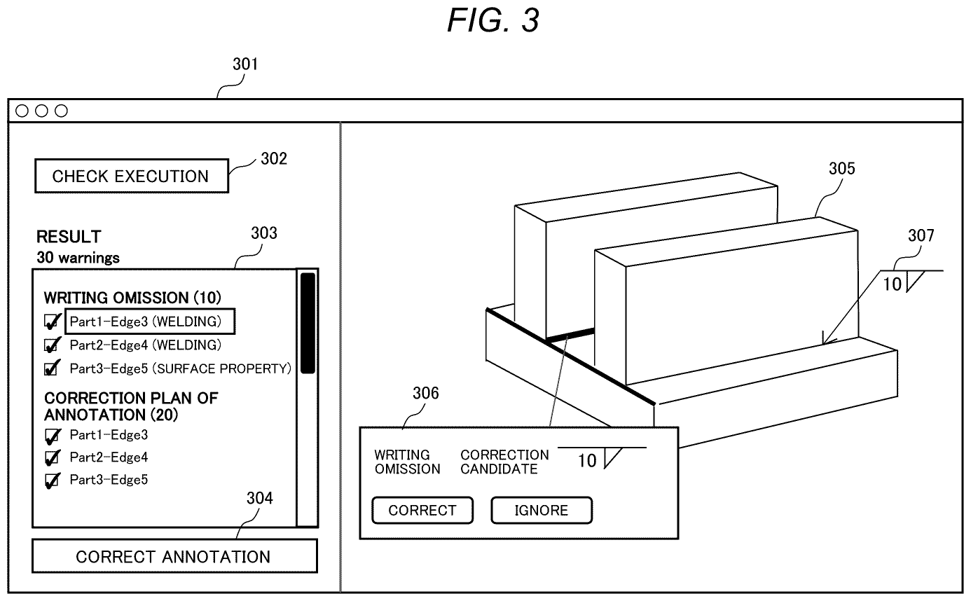

Next, display details according to this embodiment will be described. FIG. 3 is a diagram illustrating one example of a display screen 301 of the display unit 109 according to this embodiment. In a left part of the display screen 301, a check execution button 302, a result list 303, and a correction button 304 are displayed. In addition, in a right part of a presentation section, a CAD model object 305 of a target object and a correction instruction button area 306 are displayed. Here, the CAD model object 305 represents an input CAD model 114. In addition, in the vicinity of the CAD model 114, welding 307 that is predicted annotation information is displayed. Hereinafter, details of the display screen 301 will be described.

First, the 3DA predicting unit 108 predicts 3DA feature quantities of a target CAD model using the learning model 115 constructed by the learning unit 102. Then, the 3DA predicting unit 108 causes the display unit 109 to display the display screen 301 described above. At this time, the predicted 3DA feature quantities are displayed in the result list 303.

Then, when the operation unit 110 receives an operation of pressing the check execution button 302 from a user, check results relating to 3DA feature quantities included in the result list are sent to the 3DA predicting unit 108. Then, the 3DA predicting unit 108 predicts 3DA feature quantities again in accordance with the check results. In this way, a prediction with higher accuracy can be realized. In addition, in a case in which a prediction result among the prediction results of which prediction reliability is high and which is different from a 3DA feature quantity that has already been input is predicted, the 3DA predicting unit 108 adds the prediction result to the result list 303 and displays prediction result.

In the description presented above, although 3DA feature quantities (check results) that have been predicted once are checked again, the re-check may be omitted. In other words, when the check execution button 302 is pressed, the 3DA predicting unit 108 executes a prediction (check) for the CAD model 114 and displays the result in the result list 303.

In the result list 303, prediction items for each presented reason are presented. As presented reasons, a writing omission plan, a correction plan, and the like can be used. In the example illustrated in FIG. 3, “Writing Omission (10) ” is used as a writing omission plan, and “Correction Plan of Annotation (20)” is illustrated as a correction plan. These include a type of predicted 3DA feature quantity and a corresponding feature (for example, a shape) for each prediction item.

In addition, the user selects a correction plan or a writing omission plan desired to be employed from the result list 303 by operating the check execution button 302 or the like. For example, when the correction button 304 is pressed, a prediction item selected by the user is sent to the 3DA correcting unit 111. Then, the 3DA correcting unit 111 corrects 3DA feature quantities of the selected prediction item. As a result, the corrected 3DA feature quantities are reflected in a CAD model represented by the CAD model object 305. In addition, when a prediction item in the result list 303 is selected, in a right part of the screen, a shape (part) corresponding to the 3DA feature quantities displayed in the result list 303 and the selected 3DA feature quantities is displayed with being highlighted on the CAD model object 305. When the highlighted part is designated through clicking or the like, the 3DA correcting unit 111 displays a correction plan of the 3DA feature quantities for the corresponding part in the correction instruction button area 306. In addition, the user can choose to perform correction or not to employ the correction plan by ignoring it through a button operation of the correction instruction button area 306. In case of correction the 3DA correcting unit 111 finalizes the correction by storing the corrected 3DA feature quantities in the storage unit 101 and the like. In case of ignoring, the 3DA correcting unit 111 cancels the correction by deleting the corrected 3DA feature quantities or the like. By receiving selection of some of the prediction items in the result list 303 from the user, the 3DA correcting unit 111 can correct a part of the correction plan, for example, a welding depth or the like.

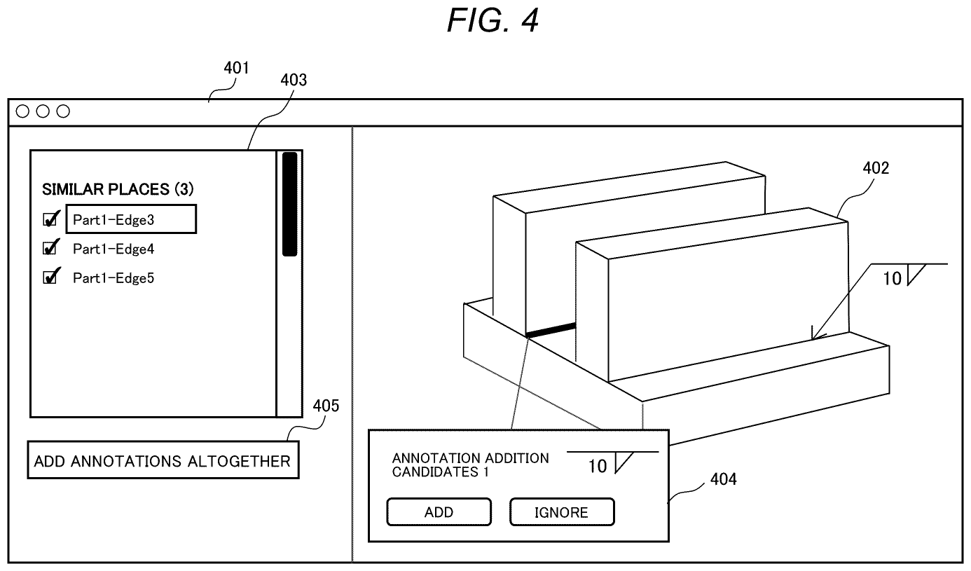

Next, FIG. 4 is a diagram illustrating another example of the display screen 401 of the display unit 109 according to this embodiment.

FIG. 4 is a use case different from FIG. 3 and is the display screen 401 of the display unit 109 to assist the input of 3DA feature quantities. In FIG. 4, in a left part of the display screen 401, a similar part list 403 and an add button 405 are displayed. In addition, in a right part of the display screen 401, a CAD model object 402 and an add instruction button area 404 are displayed. Here, the CAD model object 402 is in the process of assigning 3DA feature quantities. In this screen example, the CAD model object 402 acquired when 3DA feature quantities of a fillet welding part are assigned to one part (one portion) is displayed. In the assigning of these 3DA feature quantities, a CAD model of the CAD model object 402 is sent to the 3DA predicting unit 108, and a prediction of 3DA feature quantities is performed by the 3DA predicting unit 108.

Then, the 3DA predicting unit 108 derives a part of which type is the same as that of 3DA feature quantities that have been predicted immediately before among prediction results in this prediction and of which the shape is the same as or similar to that thereof. The 3DA predicting unit 108 sets the derived part as a candidate for the part of which 3DA feature quantities are to be predicted next. Then, the 3DA predicting unit 108 predicts 3DA feature quantities of a candidate part and presents these to the similar part list 403 for each prediction item corresponding to the part. Like the add instruction button area 404, the 3DA predicting unit 108 may display these candidates in association with the CAD model object 402. Like the prediction items illustrated in FIG. 3, a prediction item can be selected from the similar part list 403 or the add instruction button area 404 by the user. In addition, in accordance with a user pressing the add button 405 or an “Add” button of the add instruction button area 404, a corresponding prediction item is sent to the 3DA correcting unit 111. Then, the 3DA correcting unit 111 identifies 3DA feature quantities of the sent prediction item, adds the 3DA feature quantities to a corresponding CAD model, and stores the 3DA feature quantities in the storage unit 101. The description of the display screen according to this embodiment has been presented as above, and subsequently, the processing flow of this embodiment will be described. In the processing flow according to this embodiment, learning and a prediction of 3DA feature quantities using the learning model 115 constructed as a result thereof are included.

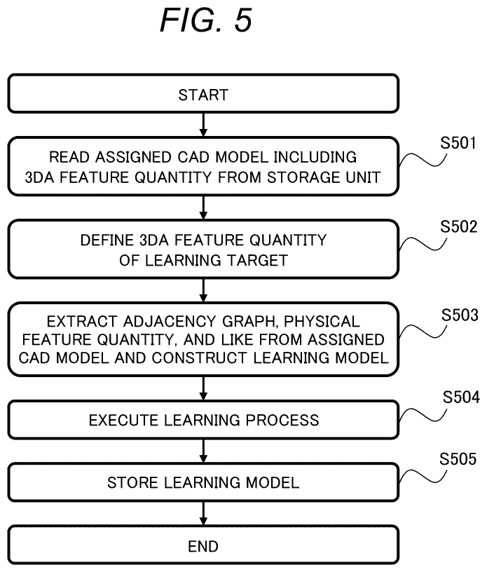

First, learning will be described. FIG. 5 is a flowchart illustrating a processing flow for learning a relationship between 3DA feature quantities and a CAD model according to this embodiment. This processing flow is executed in accordance with addition of the CAD model 114 to the storage unit 101 or periodically in batches. First, in Step S501, the learning unit 102 reads the assigned CAD model 113 that is a learning target from the storage unit 101. At this time, the assigned CAD model 113 may be read through the connecting unit 107. In this case, the connecting unit 107 may receive the assigned CAD model 113 from an external device connected to a network. In addition, in accordance with an operation on the operation unit 110, the assigned CAD model 113 may be read. The assigned CAD model 113 includes 3DA feature quantities. For this reason, as the 3DA feature quantities, 3DA feature quantities that were predicted and assigned in the past can be used.

In Step S502, the 3DA feature quantity extracting unit 103 selects 3DA feature quantities of a target to be learned this time in response to operations such as operation unit 110. Then, the 3DA feature quantity extracting unit 103 extracts the corresponding 3DA feature quantities from the assigned CAD model 113. This results in the definition of the 3DA feature quantities of a target to be learned.

Here, learning according to this embodiment may be performed for a plurality of types of 3DA feature quantities or may be performed for a single type of 3DA feature such as welding, attribute information, or the like. In a case in which learning is performed for a plurality of types of 3DA feature quantities, a learning model 115 may be constructed and implemented for each 3DA feature quantity. The 3DA feature quantities learned in this way are defined in Step S502.

In Step S503, the adjacency graph extracting unit 104 constructs an adjacency graph on the basis of the relationship of each part of a target object defined in the assigned CAD model 113. In addition, the relationship includes an adjacency relation and a connection relation. For this reason, in this step, for example, as the relationship, an adjacency relation of faces and sides or a spatial adjacency relation between faces can be used.

The physical feature quantity extracting unit 105 extracts physical feature quantities that are physical features of parts such as faces or sides. The physical feature quantities include faces, types of sides, an area, a length, curvature, a normal line, mesh information, coordinates, bounding box information, a rendered image, and the like that are geometric features. The learning model constructing unit 106 associates 3DA feature quantities and physical feature quantities defined in Step S502 with the constructed adjacency graph. Then, the learning model constructing unit 106 constructs a learning model 115 such that an associated adjacency graph can be input thereto. As this learning model 115, a graph deep learning model such as a message passing neural network and a graph learning model based on a graph kernel and the like are included. In the learning model 115, alternatively, a method for learning rule-based calculation of features of each adjacent face and each side, judgment logics according to a rule-based technique and a machine learning technique, and the like for each face and each side are included.

In Step S504, the learning model constructing unit 106 performs a learning process for predicting 3DA feature quantities of each node and each edge for physical feature quantities of an adjacency graph acquired from the assigned CAD model 113 for the learning model 115. For example, for a graph deep learning model, the learning model constructing unit 106 updates weights included in the learning model 115 using stochastic gradient descent or the like such that an empirical loss calculated from learning data formed from the adjacency graph described above is minimized. As a result, in Step S505, the learning model constructing unit 106 stores the learning model 115 of which the weights have been updated in the learning model storing unit 112.

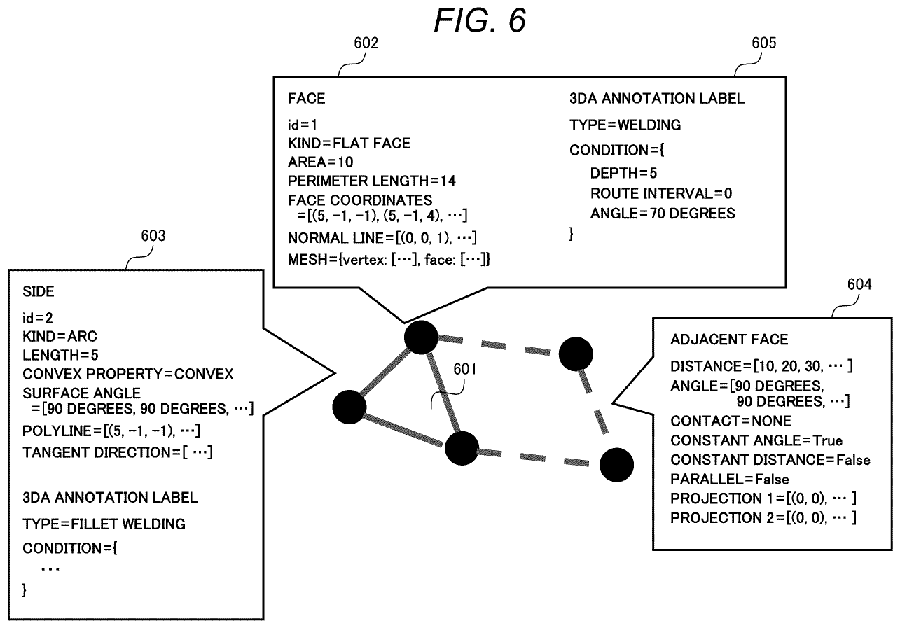

Here, specific examples of 3DA feature quantities, an adjacency graph, and physical feature quantities defined and extracted in Step S502 and Step S503 will be described. FIG. 6 is a diagram illustrating one example of 3DA feature quantities, an adjacency graph, and physical feature quantities according to this embodiment. In FIG. 6, an adjacency graph 601 is a graph in which faces are set as nodes, and sides and spatially adjacent faces are set as edges. This adjacency graph 601 is constructed from information of BREP. Each node has physical feature quantities 602 of the face being associated with 3DA feature quantities that are prediction targets by the physical feature quantity extracting unit 105. As illustrated in the drawing, as the physical feature quantities 602 of a face, a type, an area, a perimeter, face coordinates, a normal line, curvature, and a mesh are used. Other than that, as the physical feature quantities 602 of a face, a rendered image may be used.

On each edge, the physical feature quantities 603 of a side are associated with 3DA feature quantities that are prediction targets by the physical feature quantity extracting unit 105. As illustrated in the drawing, as the physical feature quantities 603 of the side, a type, a length of the side, convexity, an angle of an adjacent face, a polyline, and a tangent direction are used.

An edge representing a spatially adjacent face is associated with physical feature quantities 604 of spatially adjacent faces including a distance between the faces, an angle, presence/absence of contact, parallelism, mutually-projected shapes, and the like. Such physical feature quantities are combined into a one vector for each node and for each edge at the time of learning by the learning model constructing unit 106. In order to calculate physical feature quantities of each node and each edge by combining physical feature quantities into one vector, the learning model constructing unit 106 can perform the following processes.
Linear transformation process of physical feature quantities
Combining process of physical feature quantities
Convolution operation of physical feature quantities having numerical array values
Process of converting into one vector through pooling process
Mesh convolution process
Process of combining one-hot encoding and the like of category values
Process of combining each process and each arithmetic operation described above

Next, 3DA feature quantities that are prediction targets, that is, 3DA feature quantities associated with the physical feature quantities will be described. Here, 3DA feature quantities 605 described as 3DA feature quantities associated with physical feature quantities 602 of a face as an example are associated with the physical feature quantities 602 of the face for each node and each edge, and, as the 3DA feature quantities, a type thereof and conditions as an example of the property are included. In the example illustrated in FIG. 6, welding is illustrated as the type. In addition, as the conditions, welding depth=5, root spacing=0, and angle=70 degrees are used. When such 3DA feature quantities are to be learned, the 3DA feature quantities are converted into a vector value through one-hot-encoding or the like such that they become objective variables at the time of learning. The type, the property, and the like of 3DA feature quantities may be predicted together through multi-tasking or may be separately predicted.

As necessary, by using a method of self-supervised learning such as contrastive learning, an auto encoder, or the like, learning may be performed without training data of 3DA feature quantities. In this case, a learning model 115 that calculate physical feature quantities of a face or a side as a vector value can be constructed. The description of the learning has been presented as above. Subsequently, a processing flow including a prediction of 3DA feature quantities and the like using the learning model 115 constructed using this learning will be described.

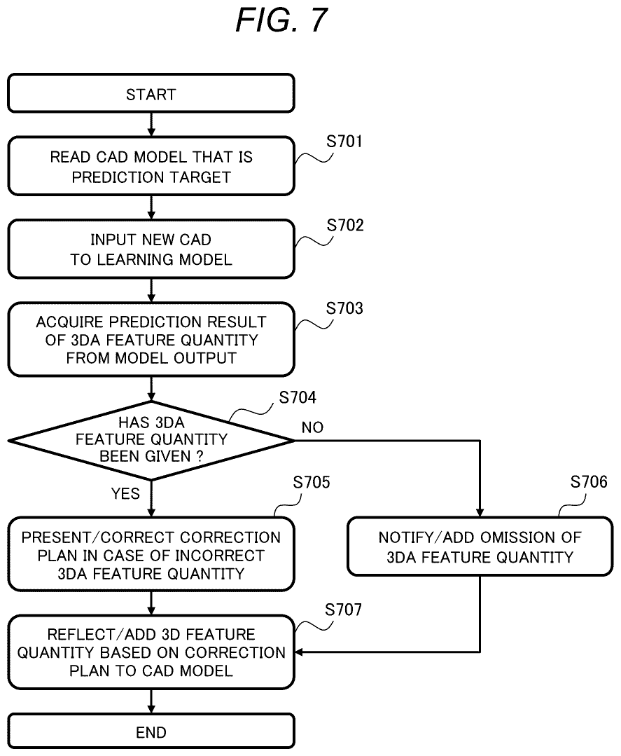

FIG. 7 is a flowchart illustrating a processing flow using the learning model 115 according to this embodiment. First, in Step S701, the connecting unit 107 reads a CAD model 114 that is a prediction target. For example, a new CAD model 114 is read.

In Step S702, the 3DA predicting unit 108 identifies a learning model 115 for predicting 3DA of the CAD model 114. For this reason, for example, this may be realized by the 3DA predicting unit 108 reading a corresponding learning model 115 from learning models 115 that have been constructed in the processing flow illustrated in FIG. 5 and are stored in the learning model storing unit 112. In addition, the 3DA predicting unit 108 may newly construct a learning model 115 on the basis of a method of extracting physical feature quantities or an adjacency graph, logics of learning, and information including weights of learning results included in the learning model 115. Then, the 3DA predicting unit 108 inputs a CAD model 114 to the identified learning model 115.

As a result, in Step S703, the 3DA predicting unit 108 predicts 3DA feature quantities in the CAD model 114. In other words, the 3DA predicting unit 108 acquires prediction results of 3DA feature quantities for each part, for example, each face of the CAD model 114 from an output of the learning model 115. Here, it is preferable that the prediction results of 3DA feature quantities include likelihood information of types of 3DA feature quantities to be assigned. In this case, in a case in which the likelihood exceeds a certain threshold value, the 3DA predicting unit 108 associates the prediction results with each part such as a face or a side as 3DA feature quantities. As a result, 3DA feature quantities as illustrated in FIG. 6 are acquired.

In addition, as is necessary, the 3DA predicting unit 108 can filter prediction results on the basis of the type of 3DA features and a shape similarity score. This shape similarity score can be calculated by a subgraph matching algorithm or the like using feature vectors of faces and sides and the topology of an adjacency graph acquired as a result of item supervised learning without using the 3DA feature quantities described above as training data. Then, the 3DA predicting unit 108 displays the prediction results described above in the display unit 109.

In Step S704, the 3DA predicting unit 108 judges whether 3DA feature quantities have already been assigned to each part of the prediction results in the CAD model 114. As a result, a part to which the 3DA feature quantities have already been assigned (Yes), the process proceeds to Step S705, and the process is performed. In addition, for an unassigned part, that is, a part to which the 3DA feature quantities have not already been assigned (No), the process proceeds to Step S706, and the process is performed.

In Step S705, the 3DA correcting unit 111 compares the predicted 3DA feature quantities (prediction results) with the assigned 3DA feature quantities and presents the correction plan to the display unit 109 when they are different from each other. In other words, as illustrated in FIG. 3, the 3DA correcting unit 111 presents the predicted 3DA feature quantities as a correction plan.

In Step S706, the 3DA correcting unit 111 presents presence of assignment omission of 3DA feature quantities in the CAD model 114 and predicted 3DA feature quantities to the display unit 109 as a candidate. In other words, as illustrated in FIG. 4, the 3DA correcting unit 111 presents the predicted 3DA feature quantities as a candidate.

Then, in Step S707, the operation unit 110 receives whether to accept the correction plan and the candidate presented in Step S705 or Step S706 in accordance with a user's operation. In case of being accepted, the 3DA correcting unit 111 assigns the correction plan and the candidate that are predicted 3DA feature quantities to the CAD model 114. The 3DA correcting unit 111 stores the CAD model 114 to which the 3DA feature quantities are assigned. In this storage, it is preferable that the 3DA correcting unit 111 store the CAD model 114 to which the 3DA feature quantities have been assigned in the storage unit 101 as the assigned CAD model 113. The description of the processing flow according to this embodiment has been presented as above.

Next, an example of implementation of the design assistance device 10 according to this embodiment will be described. FIG. 8 is a diagram illustrating Implementation Example 1 in which the design assistance device 10 according to this embodiment is implemented on a computer. As illustrated in FIG. 8, the design assistance device 10 includes an input device 11 and a display 12 as user interfaces. In addition, the design assistance device 10 has an input interface (hereinafter referred to as “input I/F”) 13, a processing device 14, a display control device 15, a main storage device 17, an auxiliary storage device 18, and a communication device 19, and these are interconnected through a data bus 16. The input I/F 13 takes in a user's operation input from input device 11. For example, a CAD model 114 and the like are taken. In addition, the CAD model 114 may be stored in a storage medium such as the auxiliary storage device 18 and be taken in individually. The display control device 15 controls display in the display 12.

The processing device 14 is a so-called processor and executes various processes according to a program.

The processing device 14 is referred to as a central processing unit (CPU).

The main storage device 17 is also referred to as a memory, and information and programs used in processes performed by the processing device 14 are expanded. In other words, the CAD model 114 that has been taken in is expanded in the main storage device 17. In addition, a design assistance program 2 is expanded in the main storage device 17 as a program. The design assistance program 2 has a 3DA feature quantity extracting module 3, an adjacency graph extracting module 4, a physical feature quantity extracting module 5, a learning model constructing module 6, a 3DA predicting module 7, and a 3DA correcting module 8 for each function. Here, the design assistance program 2 causes the processing device 14 to execute functions of the 3DA feature quantity extracting unit 103, the adjacency graph extracting unit 104, the physical feature quantity extracting unit 105, the learning model constructing unit 106, the 3DA predicting unit 108, and the 3DA correcting unit 111 illustrated in FIG. 1. In other words, the functions executed on the basis of each module of the design assistance program 2 are performed by the respective units, which are illustrated in FIG. 1, having the following correspondence relations.
3DA feature quantity extracting module 3: 3DA feature quantity extracting unit 103
Adjacency graph extracting module 4: Adjacency graph extracting unit 104
Physical feature quantity extracting module 5: Physical feature quantity extracting unit 105
Learning model constructing module 6: Learning model constructing unit 106
3DA predicting module 7: 3DA predicting unit 108
3DA correcting module 8: 3DA correcting unit 111

These modules may be realized by individual programs or may be realized by programs configured by a combination of some thereof. For example, the 3DA feature quantity extracting module 3, the adjacency graph extracting module 4, the physical feature quantity extracting module 5, and the learning model constructing module 6 can be realized as a learning program, and the 3DA predicting module 7 and the 3DA correcting module 8 can be realized as a design assistance program. It is preferable that the design assistance program 2 be stored in a storage device such as the auxiliary storage device 18 or a storage medium in advance.

In addition, the assigned CAD model 113 and the learning model 115 are stored in the auxiliary storage device 18. The communication device 19 communicates with other devices via the network 40.

Some or all of the hardware included in a computer that realizes the design assistance device 10 may be replaced by a Digital Signal Processor (DSP), a Field-Programmable Gate Array (FPGA), a Graphics Processing Unit (GPU), or the like. Alternatively, some or all of the hardware may be arranged in a cloud with being centralized or distributed in servers on a network, and a plurality of users may collaborate via the network. Next, Implementation Example 2 having this configuration will be described.

FIG. 9 is a diagram illustrating Implementation Example 2 in which the design assistance device 10 according to this embodiment is implemented on a computer (server). This implementation example is an example in which a design assistance system including the design assistance device 10 is realized as so-called a cloud system. In FIG. 9, the design assistance device 10 is connected to a terminal device group 20 and a database system 30 via a network 40. The design assistance device 10 can be realized by a computer called a server.

In the design assistance device 10 of this implementation example, a processing device 14, a main storage device 17, an auxiliary storage device 18, and a communication device 19 are interconnected via a data bus 16. The processing device 14, the data bus 16, the main storage device 17, the auxiliary storage device 18, and the communication device 19 have functions similar to those illustrated in FIG. 8.

However, the auxiliary storage device 18 further stores a design guideline 1 and a CAD model 114. This design guideline 1 recodes items that should be followed in designing a target object. For example, constraints on 3DA feature quantities and physical feature quantities are recorded. The auxiliary storage device 18 stores a CAD program 9 that realizes a design function instead of the design assistance program 2. Then, the CAD program 9 is expanded in the main storage device 17, and a process according to this program is executed by the processing device 14.

The CAD program 9 has the 3DA feature quantity extracting module 3, the adjacency graph extracting module 4, the physical feature quantity extracting module 5, the learning model constructing module 6, the 3DA predicting module 7, and the 3DA correcting module 8 illustrated in FIG. 8. The CAD program 9 further has a design module 21 and a rule checking module 22 that are used for designing. Here, the CAD model 114 described above is created in accordance with the design module 21. In accordance with the rule checking module 22, it is judged whether predicted 3DA feature quantities are compliant with the design guideline 1. Each of these modules may be realized as a separate program.

The communication device 19 is connected to the terminal device group 20 and the database system 30 via the network 40. The terminal device group 20 is a computer that is used by the user and has the input device 11, the input I/F 13, the display 12, and the display control device 15 illustrated in FIG. 8 or functions similar to these. As a result, the terminal device group 20 accepts a user's operation and displays the display screen illustrated in FIGS. 3 and 4.

In addition, the database system 30 stores an assigned CAD model 113 and a learning model 115. Here, in this implementation example, the CAD model 114 and the design guideline 1 are stored in the auxiliary storage device 18. However, these are only examples, and each piece of information may be stored in other devices. For example, the 3DA feature quantity extracting module 3, the adjacency graph extracting module 4, the physical feature quantity extracting module 5, and the learning model constructing module 6 can be realized as a learning program.

The 3DA predicting module 7, 3DA correcting module 8, the design module 21, and the rule checking module 22 can be realized as a CAD program. In this case, it is preferable that the learning program is arranged on a server side such as the design assistance device 10 and the database system 30, and the CAD program is arranged on a terminal side such as the terminal device group 20.

Although the description of this embodiment has been presented as above, the present invention is not limited thereto. For example, a CAD model other than a 3D model can also be used. Furthermore, target objects are not limited to products, components, and the like. For example, the design assistance system of Implementation Example 3 may be realized by the design assistance device 10 alone or may be realized by the design assistance device 10 and the terminal device group 20.

According to this embodiment, when there is a CAD model to which specific 3DA feature quantities have been assigned, relations between the 3DA feature quantities and shapes in the CAD model are learned using the CAD model, and a learning model 115 can be constructed. For this reason, a separate data structure such as items pointed out in design reviews may not be prepared. Furthermore, since parts and places to which 3DA feature quantities need to be assigned are predicted for the CAD model 114, assignment omissions and writing errors of 3DA feature quantities according to a designer (user) can be prevented. In addition, in a case in which prediction accuracy is high, 3DA feature quantities can be automatically assigned. According to the description presented above, this embodiment reduces designer's efforts required for assigning 3DA feature quantities.

The above points can be rephrased as below. According to this embodiment, relationships between assigned CAD models that are past CAD models and 3DA feature quantities assigned to each model are learned. In learning, spatial adjacency relations of parts such as faces, sides, and faces of the CAD model are represented as an adjacency graph in which faces are set as nodes, and sides/spatial adjacency relations are set as edges, and features of the faces and the sides are associated with each node and each edge. Next, the 3DA feature quantities that are assigned to nodes and edges of the adjacency graph are associated to learn the relationships.

In addition, it is known that a search for a similar shape among components and a prediction of features can be performed by using an adjacency graph. For example, in the case of 3DA feature quantities relating to welding as an example, locations for groove welding and the like are designed in shapes allowing groove welding, and it can be understood that there is a relationship between places to which 3DA feature quantities are assigned and shapes of components. Thus, by learning the adjacency graph, the regularity between 3DA feature quantities and shapes of places to which they are applied can be perceived. As a result, for a new CAD model, it can be predicted which 3DA feature quantities are assigned to a face or a side thereof on the basis of learning results. In accordance with this, not only past similar products (target objects) can be presented, but it can be specifically presented which 3DA features will be assigned to a certain part of the CAD model.

### REFERENCE SIGNS LIST

10 Design assistance device
101 Storage unit
102 Learning unit
103 3DA feature quantity extracting unit
104 Adjacency graph extracting unit
105 Physical feature quantity extracting unit
106 Learning model constructing unit
107 Connecting unit
108 3DA predicting unit
109 Display unit
110 Operation unit
111 3DA correcting unit
112 Learning model storing unit
113 Assigned CAD model
114 CAD model
115 Learning model

1. A design assistance system predicting 3DA feature quantities which are defined on a CAD model and which are related information of a target object of design, the design assistance system comprising:
a learning unit constructing a learning model used for predicting the 3DA feature quantities using an assigned CAD model that is a CAD model to which the 3DA feature quantities and physical feature quantities representing physical features have been assigned;
a connecting unit receiving a CAD model of the target object; and
a 3DA predicting unit predicting 3DA feature quantities to be assigned to the received CAD model using the learning model.

2. The design assistance system according to claim 1, further comprising:
a 3D correcting unit correcting or adding the predicted 3DA feature quantities.

3. The design assistance system according to claim 1,
wherein the learning unit has:
a 3DA feature quantity extracting unit extracting the 3DA feature quantities from the assigned CAD model;
an adjacency graph extracting unit constructing an adjacency graph on the basis of a relationship of parts of the target object in the assigned CAD model;
a physical feature quantity extracting unit extracting physical feature quantities from the assigned CAD model; and
a learning model constructing unit constructing the learning model using the extracted 3DA feature quantities, the constructed adjacency graph, and the extracted physical feature quantities.

4. The design assistance system according to claim 3,
wherein the learning model constructing unit constructs the learning model by associating the extracted 3DA feature quantities and the extracted physical feature quantities with the constructed adjacency graph.

5. The design assistance system according to claim 4,
wherein the adjacency graph extracting unit uses an adjacency relation and a connection relation of the parts as the relationship.

6. The design assistance system according to claim 1,
wherein the 3DA feature quantities are annotation information and attribute information of the parts of the target object, and
wherein the physical feature quantities are geometric shape information and topology information of the parts of the target object.

7. The design assistance system according to claim 1, further comprising:
a storage unit storing the assigned CAD model.

8. A storage medium that stores a design assistance program for causing a design assistance device predicting 3DA feature quantities which are defined on a CAD model and which are related information of a target object of design to function as:
a connecting unit receiving an assigned CAD model that is a CAD model to which the 3DA feature quantities and physical feature quantities representing physical features have been assigned; and
a 3DA predicting unit predicting 3DA feature quantities to be assigned to the received CAD model using the constructed learning model by using the assigned CAD model.

9. The storage medium that stores the design assistance program according to claim 8, further causing the design assistance device to function as:
a 3D correcting unit correcting or adding the predicted 3DA feature quantities.

10. The storage medium that stores the design assistance program according to claim 8 or 9,
wherein the 3DA feature quantities are annotation information and attribute information of the parts of the target object, and
wherein the physical feature quantities are geometric shape information and topology information of the parts of the target object.

11. The storage medium that stores the design assistance program according to claim 10,
wherein the parts are faces, sides, unit solids, and solids of the target object.

12. A design assistance method predicting 3DA feature quantities which are defined on a CAD model and which are related information of a target object of design using a design assistance system, the design assistance method comprising:
constructing a learning model used for predicting the 3DA feature quantities using an assigned CAD model that is a CAD model to which the 3DA feature quantities and physical feature quantities representing physical features have been assigned by using a learning unit;
receiving a CAD model of the target object by using a connecting unit; and
predicting 3DA feature quantities to be assigned to the received CAD model using the learning model by using a 3DA predicting unit.

13. The design assistance method according to claim 12, further comprising:
correcting or adding the predicted 3DA feature quantities by using a 3D correcting unit.

14. The design assistance method according to claim 12, further comprising:
extracting the 3DA feature quantities from the assigned CAD model by using a 3DA feature quantity extracting unit;
constructing an adjacency graph on the basis of a relationship of parts of the target object in the assigned CAD model by using an adjacency graph extracting unit;
extracting physical feature quantities from the assigned CAD model by using a physical feature quantity extracting unit; and
constructing the learning model using the extracted 3DA feature quantities, the constructed adjacency graph, and the extracted physical feature quantities by using a learning model constructing unit.

15. The design assistance method according to claim 12, further comprising:
storing the assigned CAD model in a storage unit of the design assistance system.
